(19) United States
(12) Patent Application Publication
(10) Pub. No.: US 2025/0296294 A1
(43) Pub. Date: Sep. 25, 2025

(54) COPPER FOIL WITH RESIN, AND COPPER-CLAD LAMINATE AND PRINTED WIRING BOARD USING THE SAME

(71) Applicant: SHIN-ETSU CHEMICAL CO., LTD., Tokyo (JP)

(72) Inventors: Yoshihiro TSUTSUMI, Annaka-shi (JP); Hiroyuki IGUCHI, Annaka-shi (JP); Tadaharu IKEDA, Kanra-machi (JP); Yuki KUDO, Annaka-shi (JP)

(73) Assignee: SHIN-ETSU CHEMICAL CO., LTD., Tokyo (JP)

(21) Appl. No.: 19/078,891

(22) Filed: Mar. 13, 2025

(30) Foreign Application Priority Data
Mar. 19, 2024 (JP) 2024-043820

(51) Int. Cl. B32B 15/14; B32B 5/02; B32B 15/092; B32B 15/20; B32B 17/04; H05K 1/03

(52) U.S. Cl. CPC B32B 15/14; B32B 5/024; B32B 15/092; B32B 15/20; B32B 17/04; H05K 1/0393; B32B 2262/101; B32B 2262/128; B32B 2311/12; B32B 2363/00; B32B 2457/08

(57) ABSTRACT

A copper foil with resin including: an uncured or semi-cured thermosetting resin layer; a copper foil, wherein the thermosetting resin layer includes a thermosetting resin composition including: a maleimide compound having one or more hydrocarbon groups derived from dimer acid skeleton in one molecule; and one or more catalysts selected from the group consisting of thermal radical polymerization initiator and an anionic polymerization initiator, and maleimide compound of component is one or more compounds selected from the group including formulae (1), (2), and (3), one or more compounds of component is solid at 25° C., and a ten-point average roughness (Rz) of a surface of copper foil, the surface which contacts thermosetting resin layer, is 1.5 μm or less. An uncured or semi-cured resin layer using maleimide resin having low dielectric characteristics, high adhesiveness and low-roughness copper foil; and copper-clad laminate and printed wiring board using this copper foil with resin.

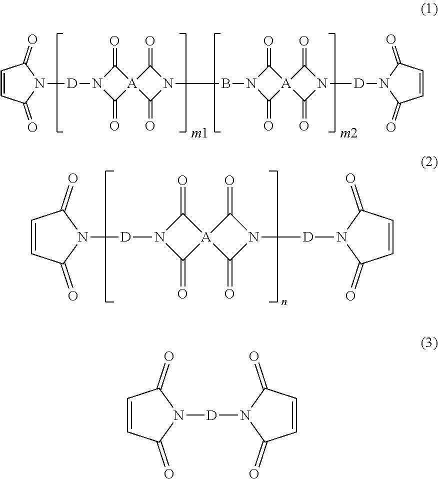

### TECHNICAL FIELD

The present invention relates to a copper foil with resin, a laminate using the resin, and a printed wiring board using the resin.

### BACKGROUND ART

A next-generation telecommunication system called “5G” has been popular in recent years. Further, development of a telecommunication system for generation after next called “6G”, which is via a wave region of 6 GHz or less called “sub-6” and beyond a millimeter-wave region of 26 GHz to 80 GHZ, has been started. To realize telecommunication with higher speed, larger capacity, and lower delay than ever, a material for a high-frequency band is required, and transmission loss will be essentially reduced for noise countermeasure.

The transmission loss is a sum of a conductor loss and a dielectric loss, and for reducing the conductor loss, roughness on a surface of used metal foil, specifically copper foil, is necessarily reduced. Meanwhile, the dielectric loss is proportional to a product of a square root of a relative permittivity and a dielectric loss tangent, and thereby there has been a demand for development of an insulative material having excellent dielectric characteristics (a low relative permittivity and a low dielectric loss tangent) as an insulative material.

Specifically, the conductor loss with high frequency is significantly affected by a skin effect, and thus material having small surface roughness becomes essential, and copper foil having low surface roughness is particularly preferably used.

To reduce the dielectric loss, a reactive polyphenylene ether resin (PPE) as a thermosetting resin, a liquid crystal polymer (LCP) or a modified polyimide (MPI) with improved properties as a thermoplastic resin, and further, polytetrafluoroethylene (PTFE) have been used as the material having a low relative permittivity and a low dielectric loss tangent. However, these materials generally exhibit low adhesiveness to the copper foil having low surface roughness, and are not a material for practically use of the low-roughness copper foil for high frequency.

In contrast, reported is use of a maleimide compound substantially having a dimer diamine skeleton (a special maleimide compound) as a main resin for a substrate (Patent Documents 1 and 2). Contrary to properties of common maleimide resins, the special maleimide compound has a low glass transition temperature (Tg) and a high coefficient of thermal expansion (CTE) but extremely excellent dielectric characteristics, and has flexible properties. In addition, the special maleimide compound has excellent adhesiveness to metal, etc., and has many advantageous points such as capability of forming a (highly) multilayered substrate due to being the thermosetting resin. The research and development has been in progress over a wide range.

As a method for producing the multilayered substrate, use of a build-up film (Patent Documents 3 to 6) has been already known. These materials, however, have a problem of considerably low adhesiveness to low-roughness copper foil having an Rz (ten-point average roughness) of 1.5 μm or less. To solve these problems, there is a concept of using a highly adhesive bonding film. However, this method requires introduction of a laminating apparatus such as a vacuum laminator, and it is difficult to apply this method for a method using a pressing machine, commonly used for producing a laminate.

Under such a background, another method for the multilayered substrate is a method of forming a multilayered substrate by using a copper foil with resin and repeating pressing and curing while heating, punching, plating, etc. This method is not frequently used in recent years, and has a problem of insufficient adhesiveness of the resin used for a prepreg in using the aforementioned low-roughness copper foil. Therefore, there has been a demand for a copper foil with resin using a resin having high adhesiveness and excellent dielectric characteristics.

As a countermeasure therefor, literature about a copper foil with resin using the above special maleimide compound is reported (Patent Document 7). However, the literature describes reduction of defects in pressing by mainly regulating a viscosity of the resin, and does not describe use of the low-roughness copper foil. In addition, the expected usage is limited substantially only to a flexible printed wiring board.

### CITATION LIST

### Patent Literature

Patent Document 1: WO 2016/114287 A1
Patent Document 2: JP 2018-201024 A
Patent Document 3: JP 2010-90236 A
Patent Document 4: JP 2010-90238 A
Patent Document 5: JP 2014-5464 A
Patent Document 6: JP 2015-101626 A
Patent Document 7: WO 2017/017923 A1

### SUMMARY OF INVENTION

### Technical Problem

The present invention has been made to solve the above problem. An object of the present invention is to provide: a copper foil with resin having an uncured or semi-cured resin layer using a special maleimide resin having low dielectric characteristics and high adhesiveness and low-roughness copper foil; and a copper-clad laminate and a printed wiring board using this copper foil with resin that has high reliability and is useful for high-speed telecommunication usage.

### Solution to Problem

To solve the above problem, the present invention provides a copper foil with resin including:
an uncured or semi-cured thermosetting resin layer; and
a copper foil, wherein
the thermosetting resin layer includes a thermosetting resin composition including:
(A) a maleimide compound having one or more hydrocarbon groups derived from a dimer acid skeleton in one molecule; and
(B) one or more catalysts selected from the group consisting of a thermal radical polymerization initiator and an anionic polymerization initiator, and
the maleimide compound of the component (A) is one or more compounds selected from the group consisting of the following formulae (1), (2), and (3), one or more compounds of the component (A) is solid at 25° C., and a ten-point average roughness (Rz) of a surface of the copper foil, the surface which contacts the thermosetting resin layer, is 1.5 μm or less,

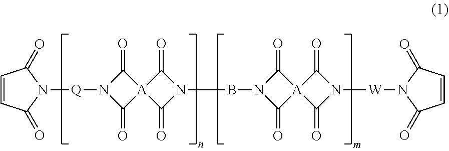

wherein “A” independently represents a tetravalent organic group having a cyclic structure; “B” independently represents a divalent hydrocarbon group having 6 to 60 carbon atoms and excluding a group having a dimer acid skeleton; “D” independently represents a group selected from the group consisting of a divalent aliphatic hydrocarbon group having 6 to 60 carbon atoms and a divalent aromatic hydrocarbon group having 6 to 60 carbon atoms, and one or more groups of “D” are a hydrocarbon group derived from a dimer acid skeleton; m1 represents 1 to 100; m2 represents 1 to 200; and an order of repeating units enclosed by parentheses subscripted with m1 and m2 is not limited, and a bonding manner may be alternate, in blocks, or at random,

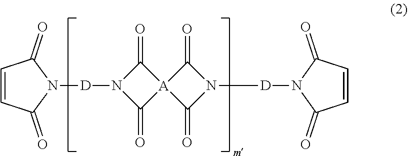

wherein “A” and “D” represent the same as defined above; one or more groups of “D” are a hydrocarbon group derived from a dimer acid skeleton; and “n” represents 1 to 100,

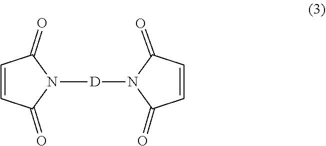

wherein “D” represents the same as defined above.

The copper foil with resin as above is a copper foil with resin using a resin having high adhesiveness and excellent dielectric characteristics.

In the present invention, “A” in the formula (1) or (2) preferably represents any one of tetravalent organic groups represented by the following formulae.

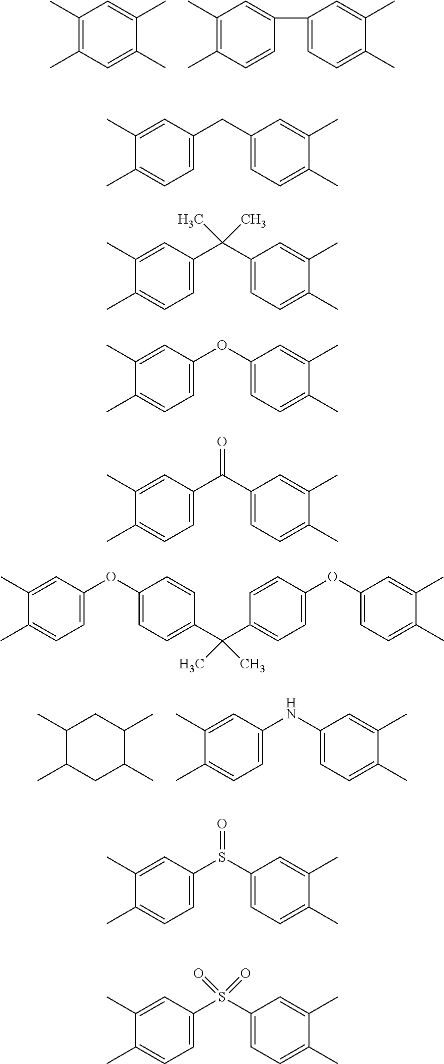

Use of the maleimide compound having a tetravalent organic group as above allows the copper foil with resin to be a copper foil with resin having further higher adhesiveness and further excellent dielectric characteristics.

In the present invention, the copper foil with resin preferably further includes an epoxy resin having two or more epoxy groups in one molecule as a component (C), wherein the component (B) is preferably an anionic polymerization initiator.

The component (B) and the component (C) as above can further promote the curing reaction of the thermosetting resin layer in the copper foil with resin.

In the present invention, the thermosetting resin layer preferably further includes glass-fiber woven fabric.

The thermosetting resin layer as above can enhance strength and rigidity of the cured product.

In addition, the present invention provides a copper-clad laminate including a cured product of the above copper foil with resin.

The copper-clad laminate as above has high adhesiveness and excellent dielectric characteristics.

In addition, the present invention provides a printed wiring board including the above copper-clad laminate.

The printed wiring board as above has high reliability and useful for high-speed telecommunication usage.

### Advantageous Effects of Invention

As above, the present invention can provide a copper foil with resin having: an uncured or semi-cured resin layer using a special maleimide resin having low dielectric characteristics and high adhesiveness; and low-roughness copper foil. The present invention can also provide a copper-clad laminate and a printed wiring board using this copper foil with resin that has high reliability and that is useful for high-speed telecommunication usage.

### DESCRIPTION OF EMBODIMENTS

As noted above, there has been a demand for development of: a copper foil with resin having an uncured or semi-cured resin layer using a special maleimide resin having low dielectric characteristics and high adhesiveness and low-roughness copper foil; and a copper-clad laminate and a printed wiring board, which use this copper foil with resin that has high reliability and that is useful for high-speed telecommunication usage.

As a result of their diligent study of the above problems, the inventor(s) found that the above object can be achieved by the following copper foil with resin, and have completed the present invention.

Specifically, the present invention is copper foil with resin including:
an uncured or semi-cured thermosetting resin layer; and
a copper foil, wherein
the thermosetting resin layer includes a thermosetting resin composition including:
(A) a maleimide compound having one or more hydrocarbon groups derived from a dimer acid skeleton in one molecule; and
(B) one or more catalysts selected from the group consisting of a thermal radical polymerization initiator and an anionic polymerization initiator, and
the maleimide compound of the component (A) is one or more compounds selected from the group consisting of the following formulae (1), (2), and (3), one or more compounds of the component (A) is solid at 25° C., and a ten-point average roughness (Rz) of a surface of the copper foil, the surface which contacts the thermosetting resin layer, is 1.5 μm or less,

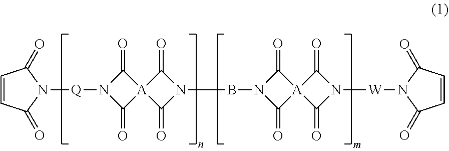

wherein “A” independently represents a tetravalent organic group having a cyclic structure; “B” independently represents a divalent hydrocarbon group having 6 to 60 carbon atoms and excluding a group having a dimer acid skeleton; “D” independently represents a group selected from the group consisting of a divalent aliphatic hydrocarbon group having 6 to 60 carbon atoms and a divalent aromatic hydrocarbon group having 6 to 60 carbon atoms, and one or more groups of “D” are a hydrocarbon group derived from a dimer acid skeleton; m1 represents 1 to 100; m2 represents 1 to 200; and an order of repeating units enclosed by parentheses subscripted with m1 and m2 is not limited, and a bonding manner may be alternate, in blocks, or at random,

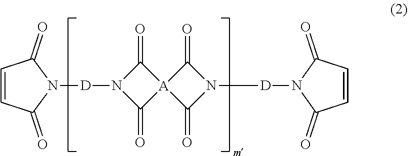

wherein “A” and “D” represents the same as defined above; one or more groups of “D” are a hydrocarbon group derived from a dimer acid skeleton; and “n” represents 1 to 100,

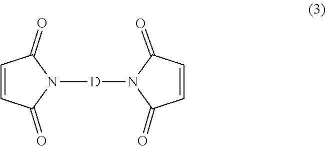

wherein “D” represents the same as defined above.

Hereinafter, the present invention will be described in detail, but the present invention is not limited thereto.

### Copper Foil

Used as the copper foil used in the copper foil with resin of the present invention is copper foil having a ten-point average roughness (Rz) of the copper foil, the surface which contacts an uncured thermosetting resin layer, described later, of 1.5 μm or less from the viewpoint of reducing the conductor loss. Rz is preferably small for reducing the conductor loss, and preferably 1.3 μm or less and more preferably 1.0 μm or less.

Although a method for producing the used copper foil is not particularly limited, the copper foil is typically produced by electrolysis or rolling in many cases, and electrolytic copper foil produced by electrolysis is used in many cases.

The used copper foil may be subjected to a surface treatment for use in order to improve adhesiveness, heat resistance, chemical resistance, etc.

A thickness of the copper foil is also not particularly limited, and copper foil having a thickness within a range of 6 to 50 μm is typically used. A thinner one is called “copper foil with a carrier” in which a carrier is attached for improving handling properties and adding thickness, and the carrier is removed in a post process. Any one of them may be used in the present invention, but the copper foil having a thickness within a range of 6 to 35 μm is preferably used.

### Thermosetting Resin Layer

The thermosetting resin layer used in the copper foil with resin of the present invention is a layer containing a thermosetting resin containing the following components (A) and (B) as essential components:
(A) A maleimide compound having one or more hydrocarbon groups derived from a dimer acid skeleton in one molecule; and
(B) One or more catalysts selected from the group consisting of a thermal radical polymerization initiator and an anionic polymerization initiator.

This thermosetting resin is characterized by being in an uncured or semi-cured state. Here, “the uncured state” refers to a so-called “A-stage”, and refers to the thermosetting resin itself that is completely not cured or a state where a vanish of the thermosetting resin with a solvent, etc. is applied into a film shape and only the solvent is evaporated. Here, “the semi-cured state” refers to a so-called “B-stage”, and refers to a state where the thermosetting resin is cured in an extent of not reaching the completely cured state.

Hereinafter, each constituent of the thermosetting resin to form the thermosetting resin layer of the present invention will be described in detail.

(A) Maleimide Compound Having One or More Hydrocarbon Groups Derived from Dimer Acid Skeleton in One Molecule

The component (A) of the present invention is a maleimide compound represented by the following formula (1), (2), or (3), and having one or more hydrocarbon groups derived from a dimer acid skeleton in one molecule. The component (A) having the hydrocarbon group derived from a dimer acid skeleton allows the cured product of the composition containing this component (A) to have low relative permittivity and dielectric loss tangent, and allows the composition after curing to have excellent film properties and handling properties. Since the component (A) has an imide group, the composition containing this component (A) exhibits high electric insulation properties even when forming a film (a thin film).

The maleimide compound of the component (A) contains at least one or more, preferably two or more, compounds of the maleimide compounds represented by the formulae (1), (2), and (3), and one or more compounds of the maleimide compounds represented by the formulae (1), (2), and (3) is solid at 25° C. Containing the solid maleimide compound as above yields excellent film properties and reduces tackiness of the uncured rein layer, and consequently improves handling properties as the copper foil with resin.

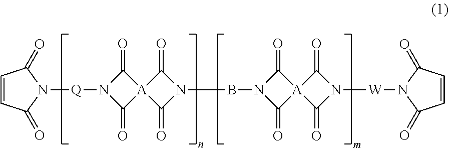

In the formula (1), “A” independently represents a tetravalent organic group having a cyclic structure; “B” independently represents a divalent hydrocarbon group having 6 to 60 carbon atoms and excluding a group having a dimer acid skeleton; “D” independently represents a group selected from the group consisting of a divalent aliphatic hydrocarbon group having 6 to 60 carbon atoms and a divalent aromatic hydrocarbon group having 6 to 60 carbon atoms, and one or more groups of “D” are a hydrocarbon group derived from a dimer acid skeleton; m1 represents 1 to 100; m2 represents 1 to 200; and an order of repeating units enclosed by parentheses subscripted with m1 and m2 is not limited, and a bonding manner may be alternate, in blocks, or at random.

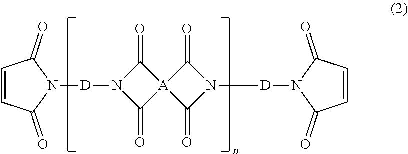

In the formula (2), “A” and “D” represent the same as defined above; one or more groups of “D” are a hydrocarbon group derived from a dimer acid skeleton; and “n” represents 1 to 100.

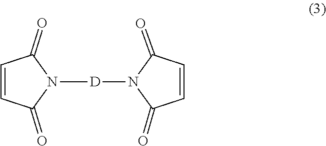

In the formula (3), “D” represents the same as defined above.

The maleimide compound having a high purity of the dimer acid, which has a ratio of the dimer acid among the skeletons derived from the dimer acid and a trimer acid being 95 mass % or more, is preferably used because the dielectric characteristics are excellent, a viscosity in heating easily decreases to have excellent formability, and an effect by moisture absorption tends to be small.

The term “dimer acid” herein refers to a liquid dibasic acid that is generated by dimerization of an unsaturated fatty acid having 18 carbon atoms derived from natural products such as vegetable oil and fat and that mainly contains a dicarboxylic acid having 36 carbon atoms. The dimer acid has a plurality of structures, not a single skeleton, and has a plurality of isomers. Representative dimer acids are classified into names of a linear type (a), a monocyclic type (b), an aromatic cyclic type (c), and a polycyclic type (d). The dimer acid skeleton herein refers to a group derived from a dimer diamine having a structure in which a carboxy group in the dimer acid as above is substituted with a primary aminomethyl group. That is, the component (A) preferably has a group as the dimer acid skeleton in which two carboxy groups are substituted with a methylene group in each of the dimer acids represented by the following (a) to (d).

The hydrocarbon group derived from a dimer acid skeleton in the maleimide compound of the component (A) more preferably has a structure with reduced carbon-carbon double bonds in the hydrocarbon group derived from a dimer acid skeleton by a hydrogenation reaction from the viewpoints of heat resistance and reliability of the cured product.

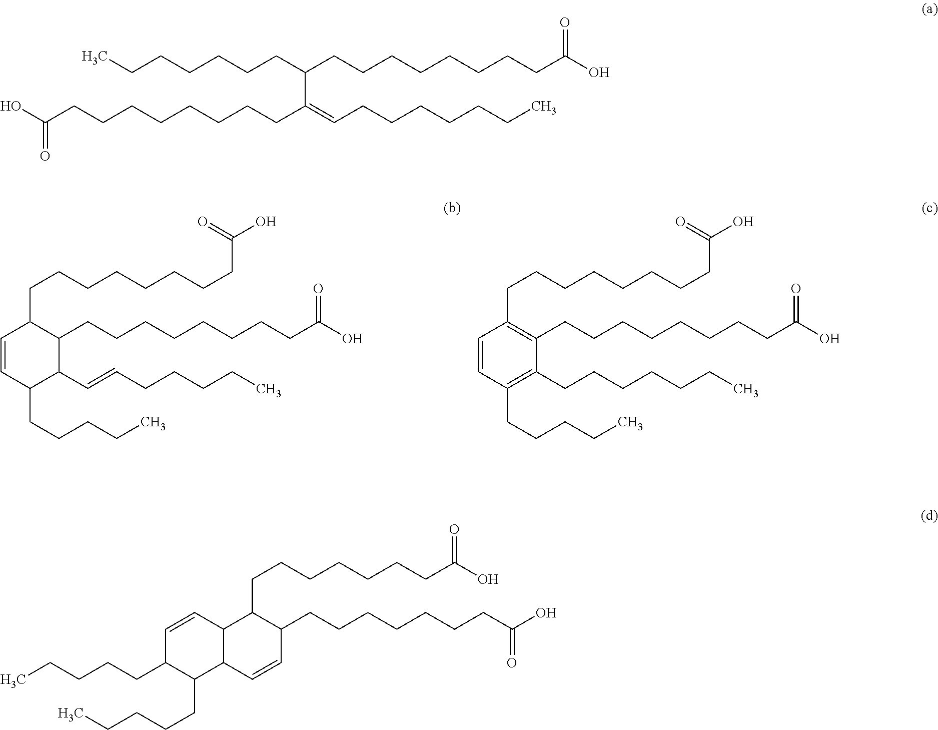 [SMILES: CCCCCCC/C=C(/CCCCCCCCC(=O)O)C(CCCCCCC)CCCCCCCCC(=O)O ; CCCCC/C=C/C1C(CCCCC)C=CC(CCCCCCCCC(=O)O)C1CCCCCCCCC(=O)O ; CCCCCCCc1c(CCCCC)ccc(CCCCCCCCC(=O)O)c1CCCCCCCCC(=O)O ; CCCCCC1C=CC2C(C=CC(CCCCCCCC(=O)O)C2CCCCCCCC(=O)O)C1CCCCC]

First, the maleimide compound represented by the formula (1) has a high melt viscosity before curing, but excellent dielectric characteristics compared with common maleimide compounds having many aromatics. In addition, the maleimide compound represented by the formula (1) exhibits high adhesiveness to the copper foil, has a smaller amount of moisture absorption than common thermosetting resins such as epoxy resins, and has a little effect due to moisture. In addition, the maleimide compound represented by the formula (1) has a higher Tg than the maleimide compound having a dimer acid skeleton represented by the formula (2), described later, and a smaller coefficient of thermal expansion (CTE) to form a composition having high reliability.

The trimer acid herein basically refers to a byproduct generated in synthesizing the dimer acid. The trimer acid is a tribasic acid that is generated by trimerization of the unsaturated fatty acid having 18 carbon atoms derived from natural products such as vegetable oil and fat and that mainly contains a tricarboxylic acid having 54 carbon atoms. Similarly to the dimer acid, the trimer acid has a plurality of structures, not a single skeleton, and has a plurality of isomers.

In the formula (1), “A” independently represents a tetravalent organic group having a cyclic structure, and specifically preferably represents any one of tetravalent organic groups represented by the following formulae.

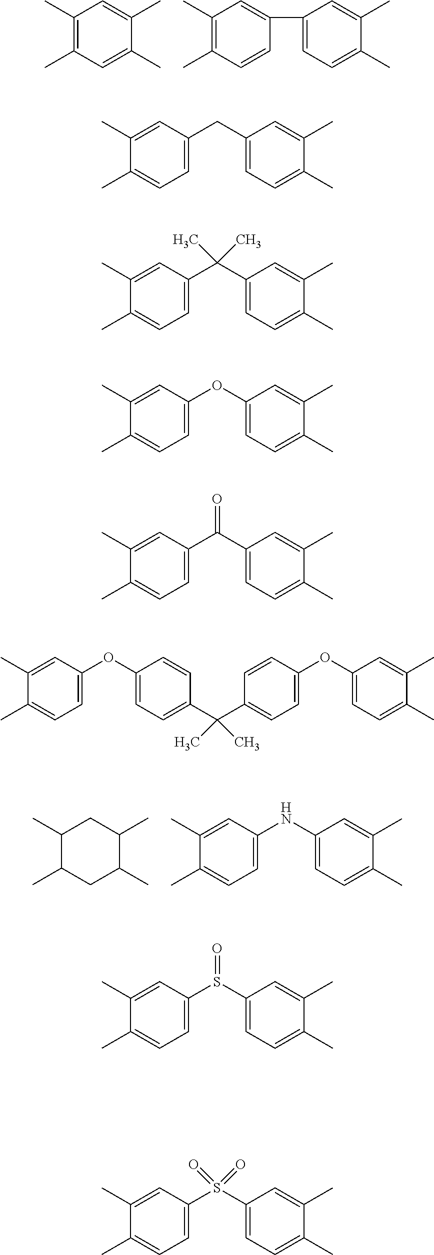

In the formula (1), “D” independently represents a group selected from the group consisting of a divalent aliphatic hydrocarbon group and divalent aromatic group, each of which has 6 to 60, preferably 8 to 60, and more preferably 10 to 55 carbon atoms. Among these, the above group is preferably a branched divalent alicyclic hydrocarbon group in which one or more hydrogen atoms in the above divalent alicyclic hydrocarbon group are substituted with an alkyl group or alkenyl group each of which has 6 to 60, preferably 8 to 60, and more preferably 10 to 55 carbon atoms. The branched divalent alicyclic hydrocarbon group may be any one of a saturated aliphatic hydrocarbon group and an unsaturated hydrocarbon group, and may have an alicyclic structure or an aromatic cyclic structure in the middle of the molecular chain.

Specific examples of the group selected from the group consisting of the divalent aliphatic hydrocarbon group and the divalent aromatic hydrocarbon group include a divalent alicyclic hydrocarbon group derived from a dual-end diamine called the aforementioned dimer diamine. One or more types in one molecule has this hydrocarbon group derived from a dimer acid skeleton.

In the formula (1), “B” independently represents a divalent hydrocarbon group having 6 to 60 carbon atoms. Specifically, “B” independently represents a divalent aliphatic hydrocarbon group having 6 to 60 carbon atoms or an aromatic hydrocarbon group having 6 to 60 carbon atoms. “B” preferably is a divalent aliphatic hydrocarbon group or aromatic hydrocarbon group each of which has 6 to 30 carbon atoms. The above divalent hydrocarbon group may have a cyclic structure and a branched structure, but have no group having a dimer acid skeleton such as the above D. The divalent aromatic hydrocarbon group may have an attachment point directly on the aromatic ring or may have an attachment point via a linear or branched divalent aliphatic hydrocarbon group on the aromatic ring.

In the formula (1), m1 represents 1 to 100, preferably 1 to 60, and more preferably 2 to 50. m2 represents 1 to 200, preferably 1 to 100, more preferably 1 to 50, and further preferably 1 to 40. The range of m1+m2 is particularly preferably a range of 2 to 40 from the viewpoints of film properties, formability, strength, etc. of the composition. Meanwhile, an excessively large m1 or m2 may decrease flowability to result in poor formability.

An order of repeating units enclosed by parentheses subscripted with m1 and m2 is not limited, and a bonding manner may be alternate, in blocks, or at random. Among these, the bonding manner in blocks is preferable from the viewpoint of easily increasing Tg.

Next, use of the maleimide compounds represented by the formula (2) yields excellent dielectric characteristics compared with other common maleimide compounds having many aromatics. Particularly, the above maleimide compound is not only effective for retaining the dielectric characteristics even with high frequency but also has strong adhesiveness to the copper foil and other resins compared with compounds represented by the formula (1), which forms an excellent composition.

In the formula (2), “A” represents the same as defined as “A” in the formula (1), and independently represents a tetravalent organic group having a cyclic structure. A preferable “A” is also the same as described above.

In the formula (2), “n” represents 1 to 100, preferably 1 to 60, and more preferably 1 to 50. An excessively large “n” may decrease solubility and flowability to result in poor formability.

Next, use of the maleimide compounds represented by this formula (3) yields excellent dielectric characteristics compared with other common maleimide compounds having many aromatics. Particularly, the above maleimide compound is effective for retaining the dielectric characteristics even with high frequency. Further, since the above maleimide compound is liquid at room temperature, the maleimide compound has effects of improving formability of the resin composition of the present invention and improving handling properties such as film properties before curing.

Thus, when the maleimide compounds represented by this formula (3) is used, the maleimide compound is preferably used in combination with any one or more compounds represented by the formula (1) or the formula (2).

As a viscosity of the component (A), a value measured based on JIS Z 8803:2011 at 25° C. by using a cone-flat plate type rotational viscosimeter at 5 rpm is preferably within a range of 1.0 to 5.0 Pa·s.

A number-average molecular weight of the maleimide compound of the component (A) is not particularly limited, but preferably 1,500 to 50,000, and more preferably 2,000 to 30,000 from the viewpoint of handling properties of the composition. The component (A) may contain another maleimide compound in addition to the compound in the formula (1), (2), or (3), or the maleimide compound may be used singly or a plurality of them may be used in combination. As noted above, when the formula (3) is used, any one or more compounds in the formula (1) or the formula (2) is preferably contained.

The number-average molecular weight referred to in the present invention refers to a number-average molecular weight measured under the following condition by gel permeation chromatography (GPC) with polystyrene as a standard substance.
Measurement Condition
Development solvent: Tetrahydrofuran (THF)
Flow rate: 0.35 mL/min
Detector: Differential refractive index detector (RI)
Column: TSK Guardcolumn SuperH-L
TSKgel SuperHZ4000 (4.6 mm I.D.×15 cm×1)
TSKgel SuperHZ3000 (4.6 mm I.D.×15 cm×1)
TSKgel SuperHZ2000 (4.6 mm I.D.×15 cm×2)
(all the above are manufactured by Tosoh Corporation)
Column temperature: 40° C.
Amount of sample injection: 5 μL (a THE solution at a concentration of 0.2 mass)
   (B) One or More Catalysts Selected from Group Consisting of Thermal Radical Polymerization Initiator and Anionic Polymerization Initiator

The component (B) is a catalyst for promoting the curing reaction of the thermosetting resin layer in the copper foil with resin of the present invention. The component (B) is added to initiate and promote a crosslinking reaction of the maleimide compound of the component (A) or a reaction with a reactive group that can react with the maleimide group in the component (A). The catalyst is selected from the group consisting of a thermal radical polymerization initiator and an anionic polymerization initiator.

For enhancing the reaction of the component (A) alone, the thermal radical polymerization initiator is preferable. Also, when a component (E) described later is contained and its reactive group is a group having a carbon-carbon double bond such as a maleimide group, an alkenyl group, and a (meth)acryl group, the thermal radical polymerization initiator is preferable.

Examples of the thermal radical polymerization initiator include azo compounds, organic peroxides, and persulfates, and among these, the organic peroxides are preferably used. The organic peroxides are classified into types of allyl peroxide, dialkyl peroxide, peroxide carbonate, hydroperoxide, etc., but not particularly limited thereto. Specific examples thereof include dicumyl peroxide, t-butyl peroxybenzoate, t-amyl peroxybenzoate, dibenzoyl peroxide, dilauroyl peroxide, 2,5-dimethyl-2,5-di(t-butylperoxy) hexane, 1,1-di(t-butylperoxy)cyclohexane, di-t-butyl peroxide, and dibenzoyl peroxide.

When a reactive group that can react with a maleimide in the component (E) described later is an epoxy group, a hydroxy group, or an acid anhydride group, the catalyst is preferably an anionic polymerization catalyst such as a basic compound including imidazoles and tertiary amines and organophosphorus compounds. Although imidazole or amines can be used in single polymerization of the maleimide group, these cases require caution such that the imidazole or the phosphorus compound requires extremely high temperature and a pot-life of the amines tend to become extremely short.

Particularly when a component (C) described later is contained, the component (B) acts as the anionic polymerization catalyst. Examples of the anionic polymerization catalyst include the basic compounds such as the imidazoles and the tertiary amines and the organophosphorus compounds as noted above, and the imidazoles are particularly preferably used.

The component (B) is blended at preferably 0.05 to 10 parts by mass, and more preferably 0.1 to 5 parts by mass relative to 100 parts by mass of the component (A). When another thermosetting resin described later is blended in the composition, the component (B) is blended within a range of preferably 0.05 to 10 parts by mass, particularly preferably 0.1 to 5 parts by mass, relative to 100 parts by mass of a total of the component (A) and the other thermosetting resin component. It is preferable because curability in forming the thermosetting resin film of the present invention is stabilized within the above range. In addition, it is preferable because the obtained cured product has good balance between heat resistance and moisture resistance within the above range.

One kind of the catalyst of the component (B) may be used, or two or more kinds thereof may be used in combination.

In the copper foil with resin of the present invention, a thickness of the uncured thermosetting resin layer to be laminated is not particularly determined, but preferably within a range of 1 to 150 μm, and more preferably within a range of 1 to 40 μm. Incidentally, a thickness of glass-fiber woven fabric described later needs to be considered when contained, and the thickness is preferably within a range of 40 to 125 μm.

### Other Additives

Additives may be further blended in the thermosetting resin layer of the present invention as The other additives will be exemplified necessary below.

### (C) Epoxy Resin Having Two or More Epoxy Groups in One Molecule

For the thermosetting resin layer in the copper foil with resin of the present invention, an epoxy resin having two or more epoxy groups in one molecule may be used as a component (C) in using the anionic polymerization catalyst as the component (B). The epoxy groups in the epoxy resin react with the anionic polymerization catalyst in the aforementioned component (B) to generate an active species, which then reacts with the maleimide group in the component (A) to initiate the anionic polymerization.

With considering the reactivity with the component (B), etc., the component (C) is preferably an epoxy resin having a glycidyl group.

Examples of the component (C) include a phenol-novolac epoxy resin, a bisphenol-A epoxy resin, a bisphenol-F epoxy resin, a bisphenol epoxy resin, a naphthalene epoxy resin, an anthracene epoxy resin, a naphthol epoxy resin, a xylylene epoxy resin, a biphenyl epoxy resin, a biphenyl aralkyl epoxy resin, a triphenylmethane epoxy resin, an alicyclic epoxy resin, a glycidylamine epoxy resin, a dicyclopentadiene epoxy resin, a stilbene epoxy resin, a sulfur atom-containing epoxy resin, and a phosphorus atom-containing epoxy resin.

The component (C) to be used is preferably liquid at a room temperature (25° C.) from the viewpoints of compatibility and wettability on the substrate.

A blending amount of the component (C) is preferably 0.05 to 25 parts by mass, and more preferably 0.1 to 20 parts by mass relative to 100 parts by mass of a total of the thermosetting resin including the component (A). It is preferable because a curing rate in forming becomes appropriate within the above range. In addition, the obtained cured product has good balance between heat resistance and moisture resistance. The target low dielectric characteristics are also obtained.

One kind of the epoxy resin of the component (C) may be used, or two or more kinds thereof may be used in combination.

### (D) Inorganic Filler

Into the thermosetting resin layer of the present invention, an inorganic filler (D) may be further added. The inorganic filler is blended for a purpose of increasing strength and rigidity of the cured product of the thermosetting resin layer in the copper foil with resin of the present invention or adjusting a coefficient of thermal expansion and size stability of the cured product. As the inorganic filler, fillers commonly blended in epoxy resin compositions or silicone resin compositions may be used, but the inorganic filler is preferably silica particles such as spherical silica, fused silica, and crystalline silica, and boron nitride in order not to increase the relative permittivity of an entirety of the composition.

An average particle diameter and a shape of the inorganic filler are not particularly limited, but spherical silica having an average particle diameter of 0.5 to 5 μm is particularly suitably used from the viewpoint of processability of the substrate. The average particle diameter is a value determined as a mass average value D₅₀ (or a median diameter) in particle size distribution measurement by a laser beam diffraction method.

To further improve the properties, the inorganic filler is preferably subjected to a surface treatment with a silane-coupling agent having an organic group that can react with the maleimide group. Examples of such a silane-coupling agent include an epoxy group-containing alkoxysilane, an amino group-containing alkoxysilane, a (meth)acryl group-containing alkoxysilane, and an alkenyl group-containing alkoxysilane.

As the silane-coupling agent, a (meth)acryl group-containing and/or amino-group-containing alkoxysilane is preferably used. Specific examples thereof include 3-methacryloxypropyltrimethoxysilane, 3-acryloxypropyltrimethoxysilane, N-phenyl-3-aminopropyltrimethoxysilane, N-2-(aminoethyl)-3-aminopropyltrimethoxysilane, and 3-aminopropyltrimethoxysilane.

One kind of the inorganic filler may be used, or two or more kinds thereof may be used in combination of two or more thereof. An addition amount of the inorganic filler is 0 to 500 parts by mass, and preferably 0 to 400 parts by mass relative to 100 parts by mas of the component (A).

(E) Thermosetting Resin Having Reactive Group that can React with Maleimide Group

In the present invention, a thermosetting resin having a reactive group that can react with the maleimide group may be added as a component (E) in the thermosetting resin layer. However, a resin corresponding to the aforementioned component (C) is not included as the component (E).

The type of the component (E) is not limited, and examples thereof include various resins other than the component (A), such as a melamine resin, a silicone resin, a cyclic imide resin including a maleimide compound other than the component (A), a urea resin, a thermosetting polyimide resin, a modified polyphenylene ether resin, a thermosetting acryl resin, and an epoxy-silicone hybrid resin. A phenol curing agent, an amine curing agent, an acid anhydride curing agent, and an active ester curing agent, which are used as a curing agent of the epoxy resin, are also included herein.

Examples of the reactive group that can react with the maleimide group include a maleimide group, a hydroxy group, an acid anhydride group, an alkenyl group such as an allyl group and a vinyl group, a (meth)acryl group, and a thiol group.

The reactive group of the component (E) is preferably selected from the group consisting of a maleimide group, a hydroxy group, and an alkenyl group from the viewpoint of reactivity, and more preferably an alkenyl group or a (meth)acryl group from the viewpoint of the dielectric characteristics.

A blending amount of the component (E) is preferably 0 to 60 mass % in a total of the thermosetting resins (namely, a total amount of the component (A), the component (C), and the component (E)).

### Glass-Fiber Woven Fabric

In the present invention, the thermosetting resin layer may further contain glass-fiber woven fabric. That is, in the present invention, its configuration may be the same as a prepreg when focusing only on the thermosetting resin layer. Examples of the glass-fiber woven fabric include E-glass, low-dielectric glass, quartz glass, and S-glass and T-glass. The type of the used glass is not limited, but quartz glass cloth having low dielectric characteristics is preferable from the viewpoint of utilizing the properties of the thermosetting maleimide resin composition. The glass-fiber woven fabric may be present inside or on a surface of the thermosetting resin layer, but preferably present inside the thermosetting resin layer from the viewpoints of appearance, processability, etc. A thickness of the typically used glass-fiber woven fabric is 10 μm or more and 100 μm or less, for example.

### Others

In addition to the above, a non-functional silicone oil, a reactive diluent, a thermoplastic resin, a thermoplastic elastomer, an organic synthetic rubber, a photosensitizer, a light stabilizer, a polymerization initiator, a flame retardant, a pigment, a dye, an adhesion aid, an ion-trapping material, etc. may be blended.

The silane-coupling agents such as the aforementioned epoxy-group-containing alkoxysilane, amino-group-containing alkoxysilane, (meth)acryl-group-containing alkoxysilane, and alkenyl-group-containing alkoxysilane, which are used for the surface treatment of the inorganic filler, may be blended in the uncured or semi-cured thermosetting resin layer of the copper foil with resin of the present invention, and may be further used for treating the surface of the copper foil. Specific examples of the silane-coupling agent include the same described as above.

A method for manufacturing the copper foil with resin of the present invention is not particularly limited, and examples thereof includes the followings.

First, the examples include a method in which the aforementioned thermosetting resin is dissolved in an organic solvent to prepare a vanish, and directly applied and dried on the surface of the copper foil. When the vanish is prepared, an organic solvent that dissolves the component (A) and the thermosetting resin having the reactive group that can react with the maleimide group, as the other additive, may be used without limitation. Examples of the organic solvent include anisole, tetralin, mesitylene, xylene, toluene, tetrahydrofuran (THF), dimethylformamide (DMF), dimethyl sulfoxide (DMSO), acetonitrile, methyl ethyl ketone (MEK), methyl isobutyl ketone (MIBK), and cyclohexanone, and aromatic organic solvents such as anisole, tetralin, mesitylene, xylene, and toluene are preferable. One kind of these may be used, or two or more kinds thereof may be used in combination of two or more thereof.

For example, the thermosetting resin dissolved in the organic solvent (the vanish) is applied on the substrate, and then heated at a temperature of typically 80° C. or higher, preferably 100° C. or higher for 0.5 to 20 minutes to remove the organic solvent. Setting the temperature to 130° C. or lower is preferable because the copper foil is not oxidized.

The temperature in the drying step for removing the organic solvent may be each constant, or the temperature may be raised stepwise, which can efficiently remove the organic solvent out of the composition.

Examples of a method for applying the vanish include a gravure coater, a die coater, a spin coater, a slit coater, a spray, a dip coater, and a bar coater, and not particularly limited.

As another method, the copper foil with resin can be obtained by preparing the vanish having the thermosetting resin dissolved in the organic solvent similarly to the above, applying the vanish on a releasing-treated polyethylene terephthalate (PET) film, drying the solvent to form a film, and laminating this film onto the copper foil, and releasing the PET film. The laminating condition in this case is not particularly limited, but the laminating is preferably performed by heating at a heating temperature of 80 to 130° C. at 0.1 to 1.0 MPa for 0.5 to 5 minutes.

As another method, the components are pre-mixed in advance, and extruded into a film shape by using a melting kneader for use as it is (extrusion formation).

The copper foil with resin of the present invention can be used for a copper-clad laminate and a printed wiring board. The printed wiring board is not limited to a flexible board, and the copper foil with resin can be used for a rigid board.

A method for producing the copper-clad laminate is not particularly limited, and a typical method is as follows, for example. The resin surface of the copper foil with resin according to the present invention is laminated with a vacuum laminator so as to contact a polyimide or liquid-crystal polymer (LCP) film that is used for a prepreg or a cured product thereof, or a flexible printed wiring board. Thereafter, the resin surface is laminated with pressing or the vacuum laminator while heating, and then cured in this state to produce the copper-clad laminate.

The laminating condition in this case is not particularly limited, but the laminating is preferably performed by heating at a temperature of 80 to 130° C. at 0.1 to 1.0 MPa for 0.5 to 5 minutes. The pressing condition is also not particularly limited, and the pressing is preferably performed while heating at a temperature of 150 to 200° C. at 0.1 to 1.0 MPa for 0.5 to 2 hours. When the heating curing is performed without pressing, the heating temperature and time are preferably under the above condition.

A method for manufacturing the printed wiring board is not particularly limited. For example, as a common method for the rigid board, the copper-clad laminate produced by the above method is subjected to pattern etching like a subtractive method for forming a circuit to obtain the printed wiring board. The method is not particularly limited also for the flexible board. For example, as a common method for the flexible board, the copper-clad laminate produced by the above method is subjected to pattern etching to form a circuit, and a cover lay is subjected to thermocompression bonding to obtain the printed wiring board.

### EXAMPLE

Hereinafter, Examples and Comparative Examples will be shown to specifically describe the present invention, but the present invention is not limited thereto.

### (A) Maleimide Compound

(A-1): A hydrocarbon group-containing bismaleimide compound derived from a dimer acid skeleton represented by the following formula (SLK-2600, manufactured by Shin-Etsu Chemical Co., Ltd., solid at 25° C.)

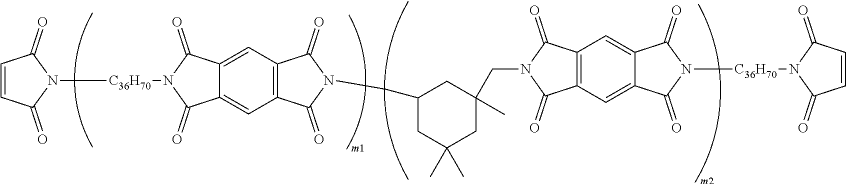

—C₃₆H₇₀-represents a structure derived from a dimer acid skeleton.

m1≈5, m2≈1

(A-2): A hydrocarbon group-containing bismaleimide compound derived from a dimer acid skeleton represented by the following formula (trade name: BMI-3000J, manufactured by Designer Molecules Inc., solid at 25° C.)

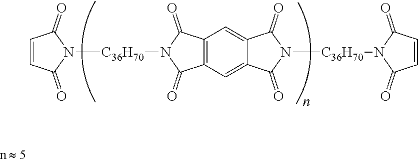

—C₃₆H₇₀-represents a structure derived from a dimer acid skeleton.

(A-3): A hydrocarbon group-containing bismaleimide compound derived from a dimer acid skeleton represented by the following formula (trade name: BMI-1500, manufactured by Designer Molecules Inc., a starch syrup form at 25° C.)

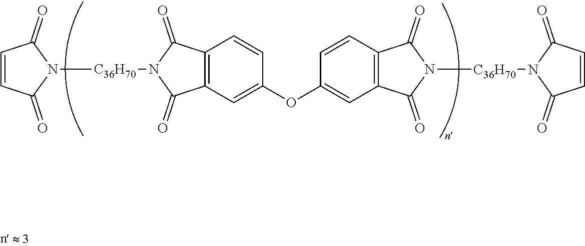

(A-4): A hydrocarbon group-containing bismaleimide compound derived from a dimer acid skeleton represented by the following formula (trade name: BMI-689, manufactured by Designer Molecules Inc., liquid at 25° C.)

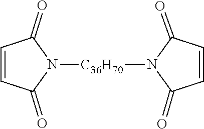

### Compounds for Comparative Examples

(A-5): 4,4′-Diphenylmethane bismaleimide (trade name: BMI-1000, manufactured by Daiwa Kasei Industry Co., Ltd., solid at 25° C.)

(A-6): An aromatic bismaleimide compound represented by the following formula (trade name: SLK-6200, manufactured by Shin-Etsu Chemical Co., Ltd., solid at 25° C.)

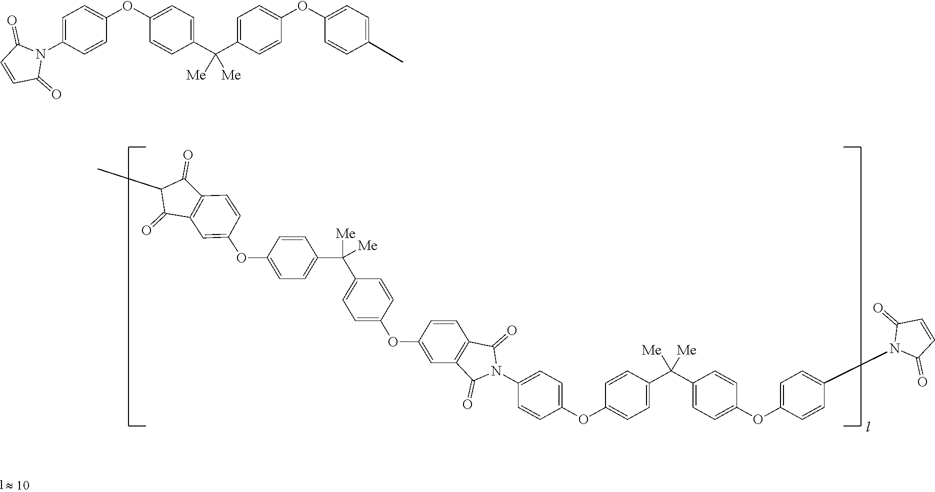

(B) One or More Catalysts Selected from Group Consisting of Thermal Radical Polymerization Initiator and Anionic Polymerization Initiator

(B-1): Dicumyl peroxide (trade name: PERCUMYL D, manufactured by NOF CORPORATION)

(B-2): 1-Benzyl-2-phenylimidazole (trade name: 1B2PZ, manufactured by SHIKOKU KASEI HOLDINGS CORPORATION)

### (C) Epoxy Resin Having Two or More Epoxy Groups in One Molecule

(C-1): A bisphenol-A liquid epoxy resin (trade name: jER-828, manufactured by Mitsubishi Chemical Corporation)

(C-2): A polyfunctional epoxy resin (trade name: EPPN-501, manufactured by Nippon Kayaku Co., Ltd.)

### (D) Inorganic Filler

(D-1): A dispersion slurry of spherical silica with 0.5 μm in average at a solid concentration of 75 mass % in a toluene dispersion liquid (trade name: 5SV-CT1, manufactured by ADMATECHS COMPANY LIMITED)

(E) Thermosetting Resin Having Reactive Group that can React with Maleimide Group

(E-1): A polyphenylene ether resin modified with methacryl at a terminal (trade name: SA-9000, manufactured by SABIC)

### (F) Comparative Material

(F-1): A hydrogenated styrene thermoplastic elastomer (SEBS) (trade name: TUFTEC H1041, manufactured by Asahi Kasei Corporation)

(F-2): A phenol novolac resin (trade name: PHENOLITE TD-2131, manufactured by DIC Corporation)

(F-3): A low-dielectric build-up film (thickness: 15 μm, trade name: GL-102, manufactured by Ajinomoto Co., Inc.)

(F-4): A low-dielectric prepreg (#1035, trade name: Megtron7 R-5785 (N), manufactured by Panasonic Industry Co., Ltd.)

### Copper Foil

Rz=1.0 μm; trade name: CF-T4X-SV-18, thickness: 18 μm, manufactured by FUKUDA METAL FOIL & POWDER CO., LTD.

Rz=5.0 μm; trade name: 3EC-III, thickness: 18 μm, manufactured by MITSUI MINING & SMELTING CO., LTD.

### Glass-Fiber Woven Fabric

Quartz glass cloth (#1035, trade name: SQX); thickness: 25 μm, manufactured by Shin-Etsu Chemical Co., Ltd.

### Preparation of Resin Vanish

The components shown in Tables 1 and 2 were fed with blending in Table 1 and Table 2 into a 500-mL four-neck flask equipped with a Dimroth condenser and a stirring apparatus, the mixture was stirred at 80° C. for 4 hours, and filtered with a 100-mesh metal net to obtain a vanish-like resin composition.

<Production of Copper Foil with Resin Having no Glass-Fiber Woven Fabric>

The vanish-like resin composition prepared above was applied on a mat surface of the above copper foil with a roller coater to produce a copper foil with resin having an uncured resin or semi-cured resin layer with 5 μm in thickness under a condition in Tables 1 and 2.

<Production of Copper Foil with Resin Having Glass-Fiber Woven Fabric>

A glass-fiber woven fabric substrate was immersed with the resin vanish prepared above at room temperature, and dried under a condition of Tables 1 and 2. A resin content (a content of the resin composition) and a thickness of the prepreg obtained in this time are each described in Tables 1 and 2. The uncured resin or the semi-cured prepreg obtained as above was laminated onto the mat surface of the above copper foil by using a batch-type vacuum laminator (manufactured by Nikko-Materials Co., Ltd.) under a condition at 100° C., a pressure of 0.5 MPa for 60 seconds to produce a copper foil with resin having glass-fiber woven fabric.

The (F-3) for comparison was not a prepreg but a film product. The cover film was peeled, the resin surface was placed on the copper foil, and then laminated onto the copper foil in accordance with the above condition in the same manner to produce a copper foil with resin. In this case, the base film was peeled before the test for use.

The (F-4) for comparison was already a prepreg, and thereby the prepreg producing step was omitted, and laminated onto the copper foil in the same manner to produce a copper foil with resin.

<Handling Properties of Copper Foil with Resin>

The handling properties of the copper foil with resin produced above were checked. A sample that was able to be wound around an ABS tube with 3 inch in diameter and that was usable without a problem was evaluated as “Good”. A sample in which cracking or peeling of the resin layer occurred when the sample was wound around an ABS tube with 3 inch in diameter was evaluated as “Poor”. A sample having considerable tackiness of the thermosetting resin layer to cause a stain in winding was evaluated as “Fair”. The samples of “Poor” and “Fair” were not subjected to the subsequent evaluations.

### <Releasing Strength>

A SUS 304 plate with 75 mm in length, 25 mm in width, and 1.0 mm in thickness was prepared. Meanwhile, the copper foil with resin produced above was cut to 150 mm in length and 10 mm in width, and the uncured or semi-cured resin layer surface was mounted thereon, and laminating was performed under a condition at 120° C., a pressure of 0.8 MPa for 60 seconds. After the laminating, the laminate was heated for curing at 180° C. for 2 hours under a nitrogen atmosphere, which prevents oxidation of copper, to produce an adhesion specimen. To evaluate the adhesiveness, measured was a 90°−releasing strength (kN/m) for releasing the copper foil of each of the adhesion specimens from the SUS plate in accordance with JIS C6481:1996 under a condition of a temperature at 23° C. and a tensile rate of 50 mm/min.

### <Heat Resistance Test>

Five of the above specimens produced for the releasing test were prepared. Those in which all five of the specimens had no abnormality after a treatment in a thermostatic chamber equipped with an air circulation apparatus set at 300° C. for 1 hour were judged as “Good”. Those in which one or more samples among the five specimens exhibited “swelling” or “peeling” were judged as “Poor”.

### <Measurement of Transmission Loss>

Two of a low-dielectric prepreg (#2016, trade name: Megtron7 R-5785 (N), manufactured by Panasonic Industry Co., Ltd.), were overlapped and laminated, and the copper foil with resin with 5 μm in thickness prepared above was overlapped on both the surfaces, and heated and pressurized under a condition of a temperature at 200° C. for 2 hours at a pressure of 3 MPa to obtain a copper-clad laminate for evaluation with about 250 μm in thickness. [Table 2]

Then, one surface of the double-sided board having the copper foil with resin on both the surfaces obtained above was processed to 100 to 200 μm in line width, and then the line width was adjusted by etching so that a characteristic impedance of a circuit after finishing was 50Ω.

The transmission loss of the obtained laminate was evaluated by using a network analyzer (manufactured by Keysight Technologies). The evaluation frequency was 40 GHz.

TABLE 1

| Blending table | | | | | | | | | | | | |
|---|---|---|---|---|---|---|---|---|---|---|---|---|
| of composition | | | Example | | | | | | | | | |
| (parts by mass) | | | 1 | 2 | 3 | 4 | 5 | 6 | 7 | 8 | 9 | 10 |
| (A) | SK-2600 | A-1 | | | | 75.0 | 75.0 | 75.0 | 70.0 | 50.0 | 50.0 | 50.0 |
| | BMI-3000J | A-2 | 100.0 | 100.0 | 100.0 | | | | | 50.0 | 50.0 | 50.0 |
| | BMI-1500 | A-3 | | | | 25.0 | 25.0 | 25.0 | 20.0 | | | |
| | BMI-689 | A-4 | | | | | | | 10.0 | | | |
| | BMI-1000 | A-5 | | | | | | | | | | |
| | SLK-6200 | A-6 | | | | | | | | | | |
| (B) | PERCUMYL | B-1 | 1.0 | | | | | | | 1.0 | | |
| | D | | | | | | | | | | | |
| | 1B2PZ | B-2 | | 1.0 | 1.0 | 1.0 | 1.0 | 1.0 | 1.0 | | 1.0 | 1.0 |
| (C) | jER-828 | C-1 | | 5.0 | 5.0 | 5.0 | 5.0 | 5.0 | 5.0 | | 5.0 | 5.0 |
| | EPPN-501 | C-2 | | | | | | | | | | |
| (D) | 5SV-CT1 | D-1 | | | 133.0 | | 100.0 | 100.0 | | 133.3 | 133.3 | 133.3 |
| | The number | | | | (100.0) | | (75.0) | (75.0) | | (100.0) | (100.0) | (100.0) |
| | in | | | | | | | | | | | |
| | parenthesis | | | | | | | | | | | |
| | indicates | | | | | | | | | | | |
| | solid | | | | | | | | | | | |
| | content | | | | | | | | | | | |
| | in parts | | | | | | | | | | | |
| | by mass. | | | | | | | | | | | |
| (E) | SA-9000 | E-1 | | | | | | | | | | |
| (F) | H1041 | F-1 | | | | | | | | | | |
| | TD-2131 | F-2 | | | | | | | | | | |
| | GL-102 | F-3 | | | | | | | | | | |
| | R-5785 | F-4 | | | | | | | | | | |
| | (N) | | | | | | | | | | | |
| Copper | Rz = | | Used | Used | Used | Used | Used | Used | Used | Used | Used | Used |
| foil | 1.0 | | | | | | | | | | | |
| | Rz = | | | | | | | | | | | |
| | 5.0 | | | | | | | | | | | |
| Glass | SQX | | | | | | | Used | | | | Used |
| fiber | | | | | | | | | | | | |
| (Sol- | Anisole | | 100.0 | 100.0 | 100.0 | 100.0 | 100.0 | 100.0 | 75.0 | 100.0 | 100.0 | 100.0 |
| vent) | Methyl | | | | | | | | | | | |
| | ethyl | | | | | | | | | | | |
| | ketone | | | | | | | | | | | |
| | (MEK) | | | | | | | | | | | |
| Drying | Temper- | ° C. | 80 | 100 | 100 | 110 | 110 | 120 | 110 | 90 | 100 | 100 |
| condi- | ature | | | | | | | | | | | |
| tion | Time | min | 2 | 2 | 2 | 2 | 2 | 2 | 2 | 2 | 2 | 2 |
| Prepreg | Thick- | μm | — | — | — | — | — | 50 | — | — | — | 51 |
| | ness | | | | | | | | | | | |
| | Resin | % | — | — | — | — | — | 60 | — | — | — | 61 |
| | content | | | | | | | | | | | |
| Eval- | Handling | | Good | Good | Good | Good | Good | Good | Good | Good | Good | Good |
| uation | properties | | | | | | | | | | | |
| results | Releasing | kN/m | 1.1 | 1.5 | 1.4 | 1.1 | 1.0 | 1.0 | 1.2 | 1.0 | 1.3 | 1.3 |
| | strength | | | | | | | | | | | |
| | Heat | | Good | Good | Good | Good | Good | Good | Good | Good | Good | Good |
| | resistance | | | | | | | | | | | |
| | test | | | | | | | | | | | |
| | Trans- | dB/10 | −2.7 | −2.9 | −2.3 | −3.0 | −2.5 | −2.0 | −2.8 | −2.6 | −2.3 | −2.0 |
| | mission | cm | | | | | | | | | | |
| | loss | | | | | | | | | | | |
| | measure- | | | | | | | | | | | |
| | ment | | | | | | | | | | | |

TABLE 2

| Blending table | | | | | | | | | | | | | | | | |
|---|---|---|---|---|---|---|---|---|---|---|---|---|---|---|---|---|
| of composition | | | Comparative Example | | | | | | | | | | | | | |
| (parts by mass) | | | 1 | 2 | 3 | 4 | 5 | 6 | 7 | 8 | 9 | 10 | 11 | 12 | 13 | 14 |
| (A) | SK-2600 | A-1 | | | | | 75.0 | | | | | | | | | |
| | BMI-3000J | A-2 | | | | 100.0 | | | | | | | | | | |
| | BMI-1500 | A-3 | 100.0 | 100.0 | 100.0 | | 25.0 | | | | | | | | | |
| | BMI-689 | A-4 | | | | | | | | | | | | | | |
| | BMI-1000 | A-5 | | | | | | 100.0 | | | | | | | | |
| | SLK-6200 | A-6 | | | | | | | 100.0 | | | | | | | |
| (B) | PERCUMYL | B-1 | 1.0 | 1.0 | 1.0 | 1.0 | | | | | | | | | | |
| | D | | | | | | | | | | | | | | | |
| | 1B2PZ | B-2 | | | | | 1.0 | 1.0 | 1.0 | 1.0 | 1.0 | 1.0 | | | | |
| (C) | jER-828 | C-1 | | | | | 5.0 | 5.0 | 5.0 | | | | | | | |
| | EPPN-501 | C-2 | | | | | | | | 61.2 | 61.2 | 61.2 | | | | |
| (D) | 5SV-CT1 | D-1 | | 266.7 | 266.7 | | 100.0 | | | 133.3 | 133.3 | 133.3 | | | | |
| | The number | | | (200.0) | (200.0) | | (75.0) | | | (100.0) | (100.0) | (100.0) | | | | |
| | in | | | | | | | | | | | | | | | |
| | parenthesis | | | | | | | | | | | | | | | |
| | indicates | | | | | | | | | | | | | | | |
| | solid | | | | | | | | | | | | | | | |
| | content | | | | | | | | | | | | | | | |
| | in parts | | | | | | | | | | | | | | | |
| | by mass. | | | | | | | | | | | | | | | |
| (E) | SA-9000 | E-1 | | | | | | | | | | | 80.0 | 40.0 | | |
| (F) | H1041 | F-3 | | | | | | | | | | | 20.0 | 80.0 | | |
| | TD-2131 | F-2 | | | | | | | | 38.8 | 38.8 | 38.8 | | | | |
| | GL-102 | F-3 | | | | | | | | | | | | | Used | |
| | R-5785 | F-4 | | | | | | | | | | | | | | Used |
| | (N) | | | | | | | | | | | | | | | |
| Copper | Rz = | | Used | Used | Used | | | Used | Used | Used | Used | | Used | Used | Used | Used |
| foil | 1.0 | | | | | | | | | | | | | | | |
| | Rz = | | | | | Used | Used | | | | | Used | | | | |
| | 5.0 | | | | | | | | | | | | | | | |
| Glass | SQX | | | | Used | | Used | | | | Used | | | | | |
| fiber | | | | | | | | | | | | | | | | |
| (Sol- | Anisole | | | | | 100.0 | 100.0 | | 200.0 | 100.0 | 100.0 | 100.0 | | | | |
| vent) | Methyl | | 50.0 | 50.0 | 50.0 | | | 250.0 | | | | | 120.0 | 200.0 | | |
| | ethyl | | | | | | | | | | | | | | | |
| | ketone | | | | | | | | | | | | | | | |
| | (MEK) | | | | | | | | | | | | | | | |
| Drying | Temper- | ° C. | 80 | 100 | 100 | 100 | 120 | 100 | 130 | 120 | 120 | 120 | 100 | 100 | — | — |
| condi- | ature | | | | | | | | | | | | | | | |
| tion | Time | min | 2 | 2 | 2 | 2 | 2 | 3 | 4 | 2 | 3 | 2 | 2 | 2 | — | — |
| Prepreg | Thick- | μm | — | — | about | — | 50 | — | — | — | 50 | — | — | — | — | 50 |
| | ness | | | | 50* | | | | | | | | | | | |
| | Resin | % | — | — | about | — | 60 | — | — | — | 60 | — | — | — | — | 65 |
| | content | | | | 60* | | | | | | | | | | | |
| Eval- | Handling | | Fair | Fair | Fair | Good | Good | Poor | Good | Good | Good | Good | Poor | Good | Good | Good |
| uation | properties | | | | | | | | | | | | | | | |
| results | Releasing | kN/m | — | — | — | 1.5 | 1.2 | — | 0.9 | 0.6 | 0.5 | 1.2 | — | 0.3 | 0.4 | 0.6 |
| | strength | | | | | | | | | | | | | | | |
| | Heat | | — | — | — | Good | Good | — | Good | Poor | Pont | Good | — | Poor | Poor | Poor |
| | resis- | | | | | | | | | | | | | | | |
| | tance | | | | | | | | | | | | | | | |
| | test | | | | | | | | | | | | | | | |
| | Trans- | dB/10 | — | — | — | −5.2 | −4.7 | — | −3.9 | −4.9 | −4.5 | 7.0 | — | −2.8 | −3.6 | −3.0 |
| | mission | cm | | | | | | | | | | | | | | |
| | loss | | | | | | | | | | | | | | | |
| | measure- | | | | | | | | | | | | | | | |
| | ment | | | | | | | | | | | | | | | |

*An accurate value failed to be obtained due to tackiness.

From the above, the usefulness of the copper foil with resin of the present invention has been confirmed from the viewpoint of adhesiveness and transmission loss.

The present description includes the following inventions.

[1]: A copper foil with resin, comprising:
an uncured or semi-cured thermosetting resin layer; and
a copper foil, wherein
the thermosetting resin layer comprises a thermosetting resin composition comprising:
(A) a maleimide compound having one or more hydrocarbon groups derived from a dimer acid skeleton in one molecule; and
(B) one or more catalysts selected from the group consisting of a thermal radical polymerization initiator and an anionic polymerization initiator, and
the maleimide compound of the component (A) is one or more compounds selected from the group consisting of the following formulae (1), (2), and (3), one or more compounds of the component (A) is solid at 25° C., and a ten-point average roughness (Rz) of a surface of the copper foil, the surface which contacts the thermosetting resin layer, is 1.5 μm or less,

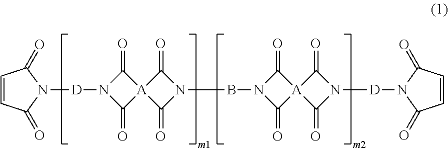

wherein “A” independently represents a tetravalent organic group having a cyclic structure; “B” independently represents a divalent hydrocarbon group having 6 to 60 carbon atoms and excluding a group having a dimer acid skeleton; “D” independently represents a group selected from the group consisting of a divalent aliphatic hydrocarbon group having 6 to 60 carbon atoms and a divalent aromatic hydrocarbon group having 6 to 60 carbon atoms, and one or more groups of “D” are a hydrocarbon group derived from a dimer acid skeleton; m1 represents 1 to 100; m2 represents 1 to 200; and an order of repeating units enclosed by parentheses subscripted with m1 and m2 is not limited, and a bonding manner may be alternate, in blocks, or at random,

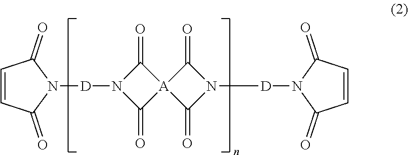

wherein “A” and “D” represent the same as defined above; one or more groups of “D” are a hydrocarbon group derived from a dimer acid skeleton; and “n” represents 1 to 100,

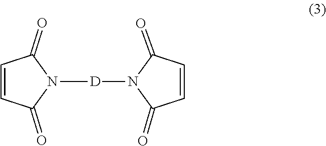

wherein “D” represents the same as defined above.

[2]: The copper foil with resin of the above [1], wherein “A” in the formula (1) or (2) represents any one of tetravalent organic groups represented by the following formulae.

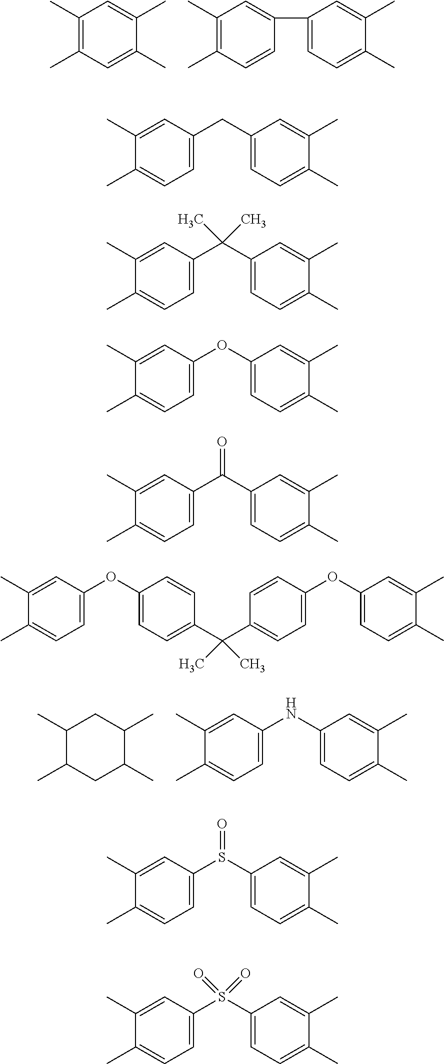

[3]: The copper foil with resin of the above [1] or [2]. 1, further comprising an epoxy resin having two or more epoxy groups in one molecule as a component (C), wherein the component (B) is an anionic polymerization initiator.

[4]: The copper foil with resin of any one of the above [1] to [3], wherein the thermosetting resin layer further comprises glass-fiber woven fabric.

[5]: A copper-clad laminate, comprising a cured product of the copper foil with resin of any one of the above [1] to [4].

[6]: A printed wiring board, comprising the copper-clad laminate of the above [5].

It should be noted that the present invention is not limited to the above-described embodiments. The embodiments are just examples, and any examples that substantially have the same feature and demonstrate the same functions and effects as those in the technical concept disclosed in claims of the present invention are included in the technical scope of the present invention.

1. A copper foil with resin, comprising:
an uncured or semi-cured thermosetting resin layer; and
a copper foil, wherein
the thermosetting resin layer comprises a thermosetting resin composition comprising:
(A) a maleimide compound having one or more hydrocarbon groups derived from a dimer acid skeleton in one molecule; and
(B) one or more catalysts selected from the group consisting of a thermal radical polymerization initiator and an anionic polymerization initiator, and
the maleimide compound of the component (A) is one or more compounds selected from the group consisting of the following formulae (1), (2), and (3), one or more compounds of the component (A) is solid at 25° C., and a ten-point average roughness (Rz) of a surface of the copper foil, the surface which contacts the thermosetting resin layer, is 1.5 μm or less, 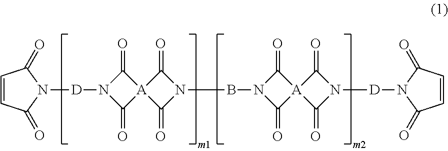
wherein “A” independently represents a tetravalent organic group having a cyclic structure; “B” independently represents a divalent hydrocarbon group having 6 to 60 carbon atoms and excluding a group having a dimer acid skeleton; “D” independently represents a group selected from the group consisting of a divalent aliphatic hydrocarbon group having 6 to 60 carbon atoms and a divalent aromatic hydrocarbon group having 6 to 60 carbon atoms, and one or more groups of “D” are a hydrocarbon group derived from a dimer acid skeleton; m1 represents 1 to 100; m2 represents 1 to 200; and an order of repeating units enclosed by parentheses subscripted with m1 and m2 is not limited, and a bonding manner may be alternate, in blocks, or at random, 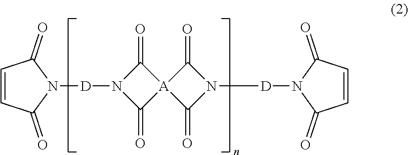
wherein “A” and “D” represent the same as defined above; one or more groups of “D” are a hydrocarbon group derived from a dimer acid skeleton; and “n” represents 1 to 100, 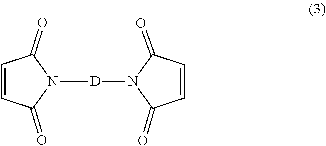
wherein “D” represents the same as defined above.

2. The copper foil with resin according to claim 1, wherein “A” in the formula (1) or (2) represents any one of tetravalent organic groups represented by the following formulae.

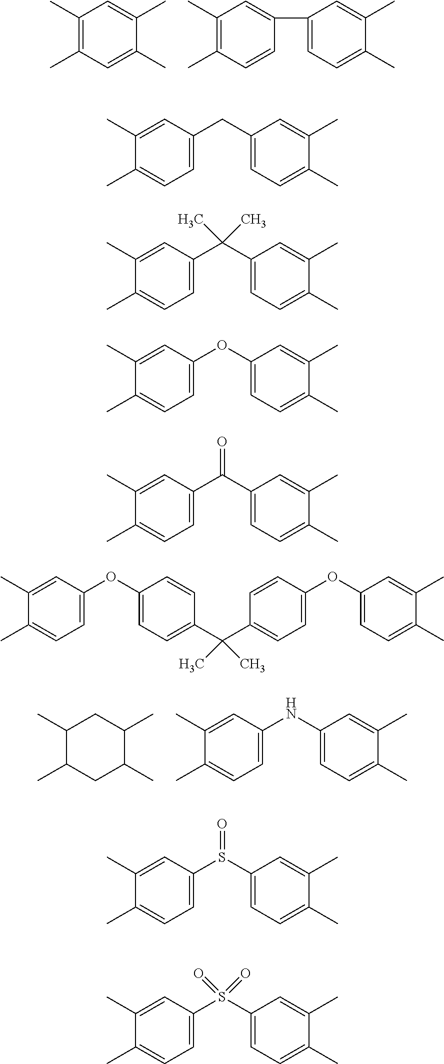

3. The copper foil with resin according to claim 1, further comprising an epoxy resin having two or more epoxy groups in one molecule as a component (C), wherein the component (B) is an anionic polymerization initiator.

4. The copper foil with resin according to claim 1, wherein the thermosetting resin layer further comprises glass-fiber woven fabric.

5. A copper-clad laminate, comprising a cured product of the copper foil with resin according to claim 1.

6. A copper-clad laminate, comprising a cured product of the copper foil with resin according to claim 2.

7. A copper-clad laminate, comprising a cured product of the copper foil with resin according to claim 3.

8. A copper-clad laminate, comprising a cured product of the copper foil with resin according to claim 4.

9. A printed wiring board, comprising the copper-clad laminate according to claim 5.

10. A printed wiring board, comprising the copper-clad laminate according to claim 6.

11. A printed wiring board, comprising the copper-clad laminate according to claim 7.

12. A printed wiring board, comprising the copper-clad laminate according to claim 8.
